(19) United States
(12) Patent Application Publication
(10) Pub. No.: US 2010/0074717 A1
(43) Pub. Date: Mar. 25, 2010

(54) AUTOMATIC TRANSPORT SYSTEM AND CONTROL METHOD THEREOF

(75) Inventors: YUNG CHIH HUANG, TAOYUAN COUNTY (TW); TSAN I CHEN, TAOYUAN COUNTY (TW); YU-KUN CHEN, TAIPEI COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: INOTERA MEMORIES, INC., TAOYUAN COUNTY (TW)

(21) Appl. No.: 12/365,387

(22) Filed: Feb. 4, 2009

(30) Foreign Application Priority Data
Sep. 24, 2008 (TW) 97136607

(51) Int. Cl. H01L 21/677

(52) U.S. Cl. 414/222.02; 414/806

(57) ABSTRACT

An automatic transport system includes: an overhead rail module having a plurality of transport rail sets, the transport rail sets each defining a bay; a plurality of overhead hoist transport vehicles movably disposed in the overhead rail module; and a control module electrically connected to the overhead hoist transport vehicles, the control module being used to control the number of the overhead hoist transport vehicles in the bays. Via this arrangement, the control module keeps some overhead hoist transport vehicles staying in each bay, thereby preventing one of the bays from having no overhead hoist transport vehicle to immediately use. This invention further provides a control method of the automatic transport system.

### BACKGROUND OF THE INVENTION

1. Field of the Invention

The present invention relates to an automatic transport system and a control method thereof, and in particular to an automatic transport system having overhead hoist transport vehicles and a control method thereof.

2. Description of Related Art

In semiconductor manufacturing, lots of wafers have to be subjected to a fabrication process with multiple steps so as to be manufactured into desired semiconductor devices. In order to obtain profit, all the semiconductor manufacturers wish to reduce the time required for manufacturing lots of wafers, thereby increasing the yield of the semiconductor fabrication plant.

There are many factors to influence the time required for manufacturing the wafers. In addition to the time required for manufacturing wafers on the respective fabrication machine tools, the time for transporting the wafers among different fabrication machine tools is also another critical factor.

The traditional transport of wafers is achieved by manpower. In this case, operators push vehicles in which wafers are carried to and from different fabrication machine tools. However, with the continuous advancement of the semiconductor manufacturing process, the size of wafer is increased from 6″, 8″ to 12″. As a result, the size of a wafer carrier for carrying wafers is increased accordingly. For example, a semiconductor plant often utilizes front opened unified pods (FOUP). When a FOUP is loaded with 25 pieces of wafers, the total weight of the wafer carrier is up to 8 kilograms, so that the traditional transport by manpower is not feasible any more. Moreover, taking the yield or other factors into consideration, it is necessary to provide a wafer transport system with high rate and efficiency, whereby the yield of a semiconductor plant can be increased. Therefore, an automatic transport system is developed for this purpose.

A common automatic transport system includes a plurality of overhead transport rail sets. A plurality of sets of fabrication machine tools is provided below each of the overhead transport rail sets. Each of the overhead transport rail sets defines a bay. The fabrication machine tools disposed in the same bay will be closely related to each other.

The transport rail sets are provided with a plurality of overhead hoist transport vehicles (OHT vehicles) or called “vehicles” for short. The vehicles move on the overhead transport rail sets, whereby the wafer carrier can be transported from one fabrication machine tool to another fabrication machine tool. Further, each of the overhead transport rail sets is connected with another overhead transport rail set, so that the vehicles can move into different overhead transport rail sets to thereby transport the wafer carrier into the fabrication machine tool of another bay.

However, the conventional automatic transport system has poor ability of sending vehicles. Thus, sometimes excess vehicles will be sent to the same transport rail set, which makes the vehicles in other transport rail sets (bays) are not enough (even no vehicle), and in turn the wafers in the bay of fewer vehicles or no vehicles cannot be transported among the fabrication machine tools immediately. Therefore, the wafers in the bay of fewer vehicles or no vehicles must spend more time in waiting for vehicles sent from other bays via the automatic transport system, which increases the total time for transporting wafers and reducing the yield of the semiconductor plant

Consequently, because of the above limitation resulting from the technical design of prior art, the inventor strives via real world experience and academic research to develop the present invention, which can effectively improve the limitations described above.

### SUMMARY OF THE INVENTION

The object of the present invention is to provide an automatic transport system and a control method thereof, whereby overhead hoist transport vehicles can be sent efficiently so as to reduce the time for assigning OHT vehicles.

In order to achieve the above objects, the present invention provides an automatic transport system, which comprises an overhead rail module having a plurality of transport rail sets, the transport rail sets each defining a bay; a plurality of overhead hoist transport vehicles movable disposed on the overhead rail module; and a control module electrically connected to the overhead hoist transport vehicles, the control module being used to control the number of the overhead hoist transport vehicles in the bays.

The present invention further provides a control method of an automatic transport system, which includes the steps of: providing an overhead rail module and a plurality of overhead hoist transport vehicles, the overhead rail module having a plurality of transport rail sets, the transport rail sets each defining a bay, the overhead hoist transport vehicles being disposed on the overhead rail module; setting a minimum number of the overhead hoist transport vehicles in each bay; activating the overhead hoist transport vehicles to move the overhead hoist transport vehicles in the overhead rail module; sending the overhead hoist transport vehicles to each bay based on the workload of the bays; and keeping the minimum number of overhead hoist transport vehicles in the bays.

The present invention has advantageous features as follows. The minimum number of overhead hoist transport vehicles is kept in each bay for immediate use, so that the problem of having no overhead hoist transport vehicles in each of the bays can be avoided.

In order to further understand the characteristics and technical contents of the present invention, a detailed description relating thereto will be made with reference to the accompanying drawings. However, the drawings are illustrative only, but not used to limit the scope of the present invention.

### BRIEF DESCRIPTION OF THE DRAWINGS

FIG. 1 is a block view showing the automatic transport system of the present invention;

FIG. 2 is a schematic view showing the automatic transport system of the present invention;

FIG. 3 is another schematic view showing the automatic transport system of the present invention;

FIG. 4 is a flow chart showing the control method of the automatic transport system of the present invention;

FIG. 5 is a block view showing the second embodiment of the automatic transport system of the present invention; and

FIG. 6 is a schematic view showing the second embodiment of the automatic transport system of the present invention.

### DETAILED DESCRIPTION OF PREFERRED EMBODIMENTS

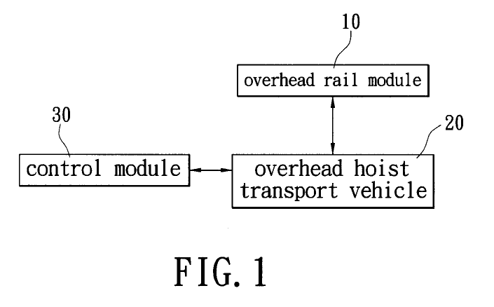

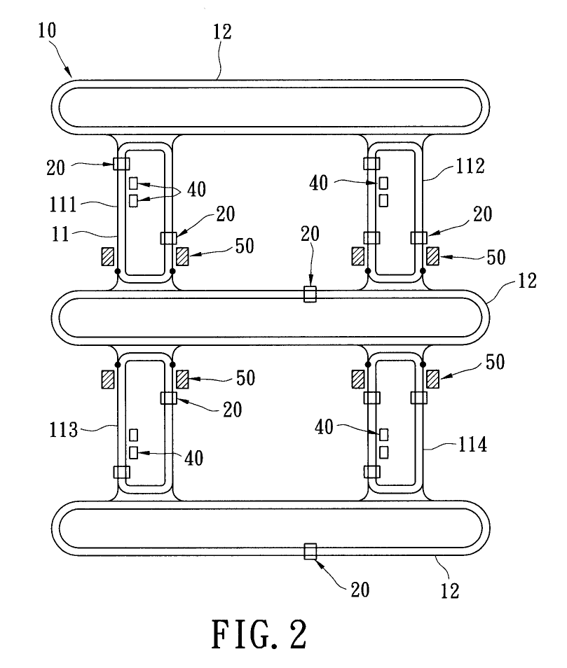

Please refer to FIGS. 1 to 3. The present invention provides an automatic transport system, which comprises an overhead rail module 10, a plurality of overhead hoist transport vehicles 20 (referred to as “vehicle” for short hereinafter), and a control module 30. The automatic transport system can be applied to various manufacturing processes. In the present embodiment, a manufacturing process for semiconductor devices is used as an example. Therefore, the automatic transport system of the present invention is provided in a semiconductor fabrication plant.

The overhead rail module 10 has a plurality of transport rail sets 11 and a plurality of connecting rail sets 12. The transport rail sets 11 are secured to a lower end of the ceiling (not shown) of a semiconductor fabrication plant. In the present embodiment, there are four groups of transport rail sets 11. For easy illustration, each group of the transport rail sets 11 is named and numbered respectively. The first transport rail set 111 is located in the upper left corner, and the second transport rail set 112 is located in the upper right corner. The third transport rail set 113 is located in the lower left corner, and the fourth transport rail set 114 is located in the lower right corner.

At least one connecting rail set 12 is connected between the respective transport rail sets 11. For example, two connecting rail sets 12 are connected between the first transport rail set 111 and the second transport rail set 112. The vehicles 20 circulate in the transport rail set 11. Alternatively, the vehicles move to different transport rail sets 11 by means of the connecting rail sets 12. The transport rail set 11 or the connecting rail set 12 defines a moving direction, such as clockwise or counterclockwise. The vehicles 20 have to follow the defined moving direction and move in the transport rail sets 11 or the connecting rail sets 12, thereby preventing two vehicles 20 from colliding with each other.

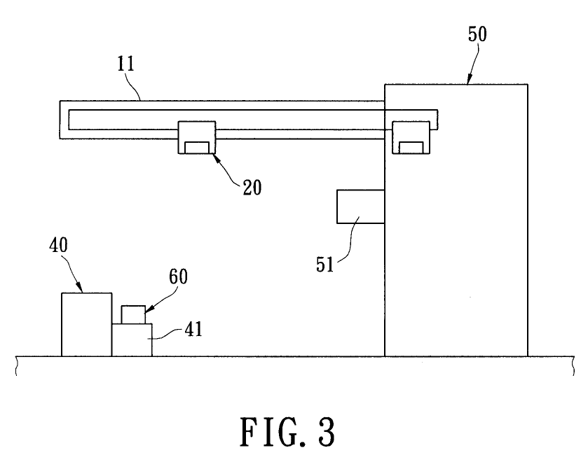

Please refer to FIG. 3. The space below a transport rail set 11 is defined as a bay. At least one fabrication machine tool 40 or stocker 50 is disposed in each bay. The fabrication machine tools 40 are used to process the wafers (not shown). The fabrication machine tool 40 may be an iron implanting machine, a photoresist coating machine or the like. The stocker 50 is used to store a wafer carrier 60.

The fabrication machine tool 40 has a loading port 41, and the stocker 50 has another loading port 51. The loading ports 41 (or 51) allow the wafer carriers 60 to be disposed therein. The vehicle 20 grips the wafer carrier 60 and transports the wafer carrier 60 from the loading port 51 of the stocker 50 to the loading port 41 of the fabrication machine tool 40, or from the loading port 41 of the fabrication machine tool 40 to the loading port 41 of another fabrication machine tool 40, or to the loading port 51 of the stocker 50.

Usually, the wafer carrier 60 is stored in the stocker 50. Then, when the wafers (not shown) in the wafer carrier 60 are subjected to a certain process, the stocker 50 will transport the wafer carrier 60 from the internal space (not shown) to the loading port 51. Then, one of the vehicles 20 moves to the upside of the loading port 51, grips the wafer carrier 60 and then moves toward the fabrication machine tool 40. Finally, the vehicle 20 puts the wafer carrier 60 on the loading port 41 of the fabrication machine tool 40. The vehicle 20 that puts the wafer carrier 60 completely will circulate in the overhead rail module 10 continuously until the vehicle 20 was assigned to transport a new wafer carrier 60.

The above description is directed to the overhead rail module 10 and the vehicle 20 of the automatic transport system of the present invention. Then, the control module 30 of the automatic transport system of the present invention will be described.

The control module 30 is electrically connected with the vehicles 20 for transmitting control signals to each vehicle 20 and assigning the vehicles 20 to transport the wafer carriers 60. The control module 30 also monitors the states of the vehicles 20 including the moving speed and the position of each vehicle 20, and whether the vehicle 20 is transporting wafer carriers 60. When an abnormal state occurs (for example, if the moving speed of the vehicle 20 is too slow), the control module 30 generates a warning signal to inform a user that he/she should check the system immediately. The signal exchange between the control module 30 and the vehicles 20 can be achieved by wireless signal transmission, including the control module 30 transmitting control signals to the vehicle 20, or the vehicle 20 transmitting signals indicative of its state to the control module 30.

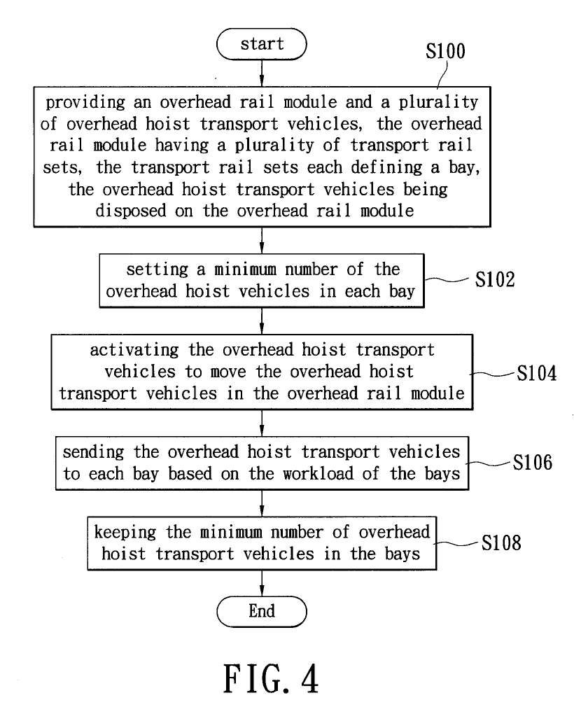

The control module 30 is to implement a control method of an automatic transport system. Please refer to FIG. 4. The control method includes the steps as follows.

In the step S100, first, the overhead rail module 10 and the vehicles 20 are provided. The overhead rail module 10 has the transport rail sets 11 with each transport rail set 11 defining a bay.

In the step S102, the minimum number of the vehicles 20 in the bays (the transport rail sets 11) is then set. For example, if the minimum number is 2, at least two vehicles 20 are kept to stay in each bay, and the at least two vehicles will not move to different transport rail set 11 by means of the connecting rail set 12.

In the step S104, the vehicles 20 are activated. In this way, the vehicles 20 move in the overhead rail module 10 to transport the wafer carriers 60 among different stockers 50 or fabrication machine tools 40.

In the step S106, the number of the vehicles 20 in each bay is adjusted based on the workload of each bay. If in a certain bay (such as the bay in the first transport rail set 111), the wafer carriers 60 have to be frequently transported between the stocker 50 and the fabrication machine tool 40. The control module 30 will send the vehicles 20 from other bays to support the work, so that the desired bay can have more vehicles 20 circulating therein. In this way, when a wafer carrier 60 is to be gripped, a vehicle 20 will come immediately to grip the wafer carrier 60.

In the step S108, finally, the minimum number of the vehicles 20 is kept in each bay. Although the vehicles 20 can move to different bays, the control module 30 will restrict the number of vehicles 20 in each bay to the predetermined minimum. When the number of vehicles 20 in one bay reaches the minimum, the vehicles 20 in this bay will not move out of this bay even other bays need more vehicles 20.

Further, the minimum number of vehicles 20 in each bay may not be the same, and can be set respectively based on the workload of each bay. If the bay is busier, the minimum number of vehicles in the bay can be set larger.

Via the above control method, the vehicles 20 can move to different bays to support the work, and some vehicles 20 will stay in each bay for standby. It is impossible for a bay to have no vehicle 20 at any time. Therefore, if a certain bay needs vehicles to grip the wafer carriers 60, the problem that this bay may have no vehicle 20 left for use and must wait vehicles 20 from other bays can be avoided. Thus, the reduction in yield caused by the above problem can be avoided.

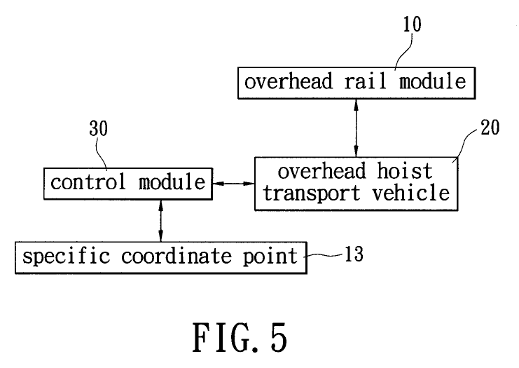

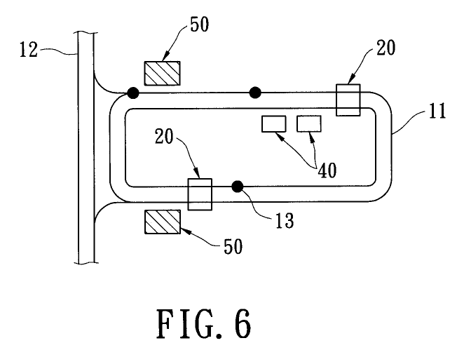

Please refer to FIGS. 5 and 6. The automatic transport system further has a second embodiment. The difference between the second embodiment and the first embodiment lies in that: the control module 30 stores a plurality of special coordinate points 13.

The special coordinate points 13 correspond to a specific fabrication machine tool 40 or a stocker 50 respectively. Taking the first transport rail set 111 as an example, a distance in front of the stocker 50 is defined as the specific coordinate point 13 of the stocker 50. A distance in front of the fabrication machine tool 40 is defined as the specific coordinate point 13 of the fabrication machine tool 40.

Each of the specific coordinate points 13 has specific service information. The specific service information includes the information related to the vehicle 20 gripping or putting a wafer carrier 60 on a certain machine tool (the fabrication machine tool 40 or the stocker 50). For example, the specific service information corresponding to the specific coordinate point 13 of the stocker 50 indicates that after the vehicle 20 grips a wafer carrier 60 from the stocker 50, the vehicle 20 continues to move forwards. Thus, when an unoccupied vehicle 20 (i.e. without a wafer carrier 60 therein) passes through the specific coordinate point 13, the control module 30 will send a control signal to the vehicle 20, so that the vehicle 20 can grip a wafer carrier 60 from the stocker 50 according to the specific service information. Then, the vehicle 20 continues to move forwards.

Via the specific coordinate point 13 in the second embodiment, when the control module 30 intends to send the vehicles 20, it simply needs to assign a vehicle 20 to a desired bay. Then, after the vehicle 20 reaches the desired bay, it will obtain a subsequent transport process from the specific coordinate point 13.

According to the above, the automatic transport system and the control method thereof according to the present invention have advantageous features as follows.

(I) The control module 30 monitors the state of each vehicle 20. When an abnormal state occurs, the control module can inform the operator that a checking process has to be performed.

(II) In each bay, a minimum number of vehicles 20 are kept for use. Therefore, the problem that a bay has no vehicles 30 will not happen.

(III) By means of the specific coordinate points 13, the time for assigning vehicles is reduced.

While the present invention has been described in terms of what is presently considered to be the most practical and preferred embodiments, it is to be understood that the present invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An automatic transport system, comprising:
an overhead rail module having a plurality of transport rail sets, the transport rail sets each defining a bay;
a plurality of overhead hoist transport vehicles movably disposed on the overhead rail module; and
a control module electrically connected to the overhead hoist transport vehicles, the control module being used to control the number of the overhead hoist transport vehicles in the bays.

2. The automatic transport system according to claim 1, wherein at least one connecting rail set is connected between the transport rail sets.

3. The automatic transport system according to claim 1, wherein the control module stores a plurality of specific coordinate points.

4. The automatic transport system according to claim 3, wherein each of the specific coordinate points has specific service information, the overhead hoist vehicles perform a desired transport based on the specific service information.

5. The automatic transport system according to claim 1, wherein the control module is used to monitor the states of the overhead hoist transport vehicles.

6. The automatic transport system according to claim 5, wherein the states of the overhead hoist transport vehicle comprise the moving speed, the position, or the load of transport of the vehicle.

7. The automatic transport system according to claim 1, wherein the automatic transport system is applied to a semiconductor fabrication plant.

8. The automatic transport system according to claim 6, wherein each bay is provided with at least one fabrication machine tool.

9. The automatic transport system according to claim 6, wherein each by is provided with at least one stocker.

10. The automatic transport system according to claim 6, wherein each of the overhead hoist transport vehicles is used to transport a wafer carrier.

11. A control method of an automatic transport system, comprising the steps of:
providing an overhead rail module and a plurality of overhead hoist transport vehicles, the overhead rail module having a plurality of transport rail sets, the transport rail sets each defining a bay, the overhead hoist transport vehicles being disposed on the overhead rail module;
setting a minimum number of the overhead hoist transport vehicles in each bay;
activating the overhead hoist transport vehicles to move the overhead hoist transport vehicles in the overhead rail module;
sending the overhead hoist transport vehicles to each bay based on the workload of the bays; and
keeping the minimum number of overhead hoist transport vehicles in the bays.

12. The control method of an automatic transport system according to claim 11, wherein the minimum number of the overhead hoist transport vehicles in each bay are different.

13. The control method of an automatic transport system according to claim 11, further comprising the steps of:
monitoring the states of the overhead hoist transport vehicles; and
sending a warning signal when the state of the overhead hoist transport vehicles is abnormal.

14. The control method of an automatic transport system according to claim 11, wherein the control method is applied to a semiconductor fabrication plant.

15. The control method of an automatic transport system according to claim 14, wherein each of the bays has at least one fabrication machine tool.

16. The control method of an automatic transport system according to claim 14, wherein each of the bays has at least one stocker.
